(19) United States
(12) Patent Application Publication
(10) Pub. No.: US 2025/0279282 A1
(43) Pub. Date: Sep. 4, 2025

(54) IN SITU REMOVABLE BLOCKING LAYER FORMATION

(71) Applicant: Tokyo Electron Limited, Tokyo (JP)

(72) Inventors: Ivo Otto, IV, Albany, NY (US); Hamed Hajibabaeinajafabadi, Albany, NY (US); Matthew Rednor, Albany, NY (US); Toshiki Kanaki, Albany, NY (US)

(21) Appl. No.: 18/591,695

(22) Filed: Feb. 29, 2024

(51) Int. Cl. H01L 21/311; H01L 21/02; H01L 29/66

(52) U.S. Cl. CPC H01L 21/31116; H01L 21/02636; H10D 64/018

(57) ABSTRACT

A method of etching a target material of a substrate includes selectively forming a blocking layer on an oxygen-containing material using ammonia gas and at least one fluorine-containing gas, etching the target material using an etchant gas, and removing the blocking layer from the oxygen-containing material by exposing the vertical stack to a temperature of at least 80° C. The substrate also includes a vertical stack of layers of a first material suspended between structures of a second material. The oxygen-containing material covers surfaces of the second material in openings between the layers of the first material. The blocking layer inhibits diffusion of the etchant gas into the second material.

### TECHNICAL FIELD

The present invention relates generally to etching processes, and, in particular embodiments, to systems and methods for etching processes that include in situ formation of a removable blocking layer.

### BACKGROUND

Microelectronic device fabrication typically involves a series of manufacturing techniques that include formation, patterning, and removal of a number of layers of material on a substrate. Etch masks may be formed (e.g., deposited, grown, patterned) to protect regions of the substrate and allow for pattern transfer via etching. Wet or dry etching processes may be used, and the directionality of the etch may be isotropic or anisotropic. Isotropic etching processes are often used to etch laterally (e.g., underneath or between materials).

Etching processes are often tailored to be selective to a specific material or class of materials. For this reason, structures of similar material composition can be etched at the same time with a particular pattern of protective structures (e.g., a single mask). However, simultaneous etching of structures with differing dimensionality can be difficult without introducing additional process steps to protect each type or structure. Differences in dimensionality that may introduce uneven etching may be critical dimension (CD), aspect ratio, feature density, height, length, shape, and others. The features that etch faster, such as the smaller structures, may expose materials sensitive to the etchant that are not the target of the etch before the larger structures have reached the etching endpoint. That is, undesirable damage due to overetching may occur to structures underlying or adjacent to etch targets that reach the endpoint faster while desirable etching continues on other structures.

Additional process steps, such as additional mask formation steps, decrease throughput. Further, more process steps can also decrease yield due to the compounding of defects at each step. Damage from overetching is also a consequence of undesirably low overetch margin (i.e., the amount of overetching that a structure can endure without impacting device yield or performance). Therefore, improved etching processes that allow etching of structures of difference dimensionality without additional process steps by improving overetch margin may be desirable.

### SUMMARY

In accordance with an embodiment of the invention, a method of etching a target material of a substrate includes selectively forming a blocking layer on an oxygen-containing material using ammonia gas and at least one fluorine-containing gas, etching the target material using an etchant gas, and removing the blocking layer from the oxygen-containing material by exposing the vertical stack to a temperature of at least 80° C. The substrate also includes a vertical stack of layers of a first material suspended between structures of a second material. The oxygen-containing material covers surfaces of the second material in openings between the layers of the first material. The blocking layer inhibits diffusion of the etchant gas into the second material.

In accordance with another embodiment of the invention, a channel release method for longer channel devices of a substrate that also includes shorter channel devices includes performing the following steps without breaking vacuum: selectively forming a blocking layer on inner spacers of the shorter channel devices; etching silicon germanium (SiGe) layers of the longer channel devices using an etchant gas; and removing the blocking layer from the inner spacers by exposing the shorter channel devices to a temperature of at least 80° C. The inner spacers cover surfaces of SiGe source/drain structures in openings between silicon (Si) layers suspended between the SiGe source/drain structures. The blocking layer inhibits diffusion of the etchant gas into the SiGe source/drain structures.

In accordance with still another embodiment of the invention, a system includes a processing chamber; a substrate support configured to support a substrate within the processing chamber, one or more valves configured to fluidically couple a blocking gas and an etchant gas to the processing chamber, and a controller operatively coupled to the one or more valves. The substrate includes a target material and a vertical stack of layers of a first material suspended between structures of a second material. The controller includes a processor and a non-transitory computer-readable medium storing a program including instructions that, when executed by the processor, perform a method without breaking a vacuum environment of the system. The method includes selectively forming, in the processing chamber, a blocking layer on an inner spacer material covering surfaces of the second material in openings between the layers of the first material using the blocking gas, etching, in the processing chamber, the target material using the etchant gas, and removing the blocking layer from the inner spacer material. The blocking layer inhibits diffusion of the etchant gas into the second material.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1D illustrate an example etching process that uses a blocking layer to inhibit diffusion while etching a target material, where FIG. 1A shows an initial state of a substrate with inner spacers in openings of a vertical stack of layers, FIG. 1B shows a selective formation step of forming a blocking layer on the inner spacers, FIG. 1C shows an etch step of etching the target material while the blocking layer inhibits diffusion, and FIG. 1D shows a removal step of removing the blocking layer in accordance with embodiments of the invention;

FIGS. 2A-2C illustrate another example etching process that uses a blocking layer to inhibit diffusion while etching a target material, where FIG. 2A shows an initial state of a substrate with inner spacers in openings of a vertical stack of layers, FIG. 2B shows an optional pretreatment step that modifies surfaces of the inner spacers, and FIG. 2C shows a combined step of selectively forming the blocking layer on the inner spacers while etching the target material in accordance with embodiments of the invention;

FIG. 3 illustrates an example system that may be used to perform one or more steps of the etching processes without breaking vacuum in accordance with embodiments of the invention;

FIG. 4 illustrates another example system that may be used to perform one or more steps of the etching processes without breaking vacuum in accordance with embodiments of the invention;

FIG. 5 illustrates an example method etching a target material of a substrate that also includes a vertical stack of layers of a first material suspended between structures of a second material in accordance with embodiments of the invention; and

FIG. 6 illustrates a conventional channel release process resulting in undesirable damage to source/drain structures of shorter channel devices.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope. Unless specified otherwise, the expressions “around”, “approximately”, and “substantially” signify within 10%, and preferably within 5% of the given value or, such as in the case of substantially zero, less than 10% and preferably less than 5% of a comparable quantity.

Microelectronic device fabrication often utilizes several etching processes to modify structures on a substrate. For example, isotropic etching processes are often used to etch laterally (e.g., underneath or between materials). One application where isotropic etching processes are used is when etching three-dimensional structures. Various three-dimensional devices, such as gate-all-around (GAA) devices utilize vertical stacks of two or more types of materials during the fabrication process. One such vertical stack of layers (e.g., alternating silicon (Si) and silicon germanium (SiGe) layer) is used in GAA field-effect transistor (FET) devices to form multibridge channels by etching away one type of layer to suspend the remaining layers (i.e., a channel release process).

During the channel release process, the sacrificial layers between the channel layers may be removed. The suspended channel layers may extend between source/drain structures. Damage to the source/drain structures during the channel release process is undesirable because it can negatively impact device performance. In some cases, the entire source/drain structure may be removed. Because the channel length between devices may vary on a single substrate, the sacrificial layers may be completely etched away in shorter channel devices while longer channel devices still need to be etched to fully release the channel layers. For this reason, overetch margin for the shorter channel devices may influence the ability to etch both the shorter channel structures and the longer channel structures during the same etching process.

Inner spacers may be formed between the sacrificial layers and the source/drain structures. The inner structures may not be significantly affected by the etchant during the channel release process (e.g., functioning as a source of increased overetch margin for the etching process). However, the inner spacers may still allow diffusion of the etchant through to source/drain structures given sufficient overetch time. Specifically, the additional etch time required to etch longer channel structures may be more (e.g., much more) than the overetch protection afforded by the inner spacers.

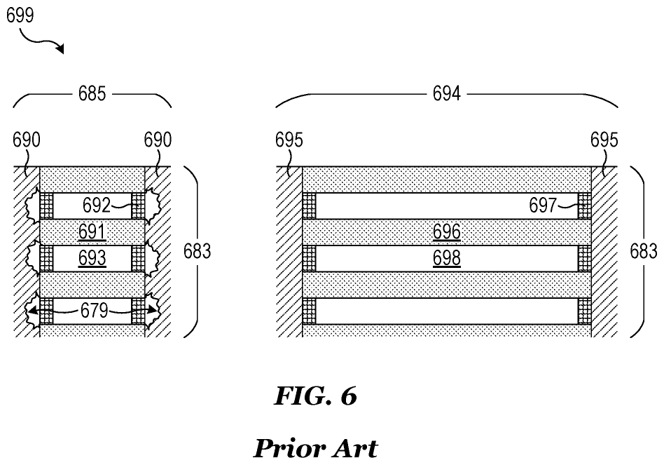

FIG. 6 illustrates a conventional channel release process 699 resulting in undesirable damage to source/drain structures of shorter channel devices. In this specific example, during the conventional channel release process 699, a substrate 683 that includes both shorter channel devices 685 and longer channel devices 694 may be etched to remove sacrificial layers from between Si short channel layers 691 and Si long channel layers 696 to form openings 693 and openings 698, respectively. The Si short channel layers 691 are then suspended between SiGe source/drain structures 690 and separated by inner spacers 692, while the Si long channel layers 696 are suspended between SiGe source/drain structures 695 and separated by inner spacers 697.

Yet, despite the presence of the inner spacers 692, the increased etch timer caused be the difference in channel length results in undesirable short channel SiGe source/drain damage 679. That is, even though the etchant gas does not negatively interact with the inner spacers 692, the etchant gas diffuses through the inner spacers 692 and etches away the SiGe source/drain structures 690. Without modification, the conventional channel release process 699 is undesirably limited by the overetch margin of the shorter channel devices 685.

Therefore, an improved etching process that increases the overetch margin for structures with smaller dimensionality while avoiding undesirable consequences, (e.g., decreased throughput, device performance, yield, process performance, etc.) are desirable both in this specific case as well as in any case where an etchant gas may diffuse through a layer to damage structures before the etching process has reached the endpoint.

In accordance with embodiments herein described, the invention proposes the selective formation of a blocking layer as part of an etching process. The blocking layer is formed on structures of a certain material composition to protect against overetching. The formation of the blocking layer may be fully integrated into the etching process, such as by both etching a target material and forming the blocking layer in situ in the same chamber. The blocking layer may be configured to inhibit or prevent undesirable diffusion of an etchant gas into nearby materials. As an example of one specific application, the blocking layer may be selectively formed on inner spacer structures of a vertical stack of channel layers to protect source/drain structures from damage while etching other regions on the same substrate (e.g., sacrificial layers for channel release of longer channel devices). After the etching of the target material reaches a desired endpoint, the blocking layer is removed.

Embodiments of the invention apparent from the description herein may have various advantages over conventional etching processes. For example, damage to certain structures (e.g., source/drain structures) may be decreased or prevented without negatively impacting process performance, such as channel release process performance, thereby increasing device yield and/or device performance. The mitigation of structural damage may be advantageously reflected in increased overetch margin compared to conventional etching processes, reducing process marginality and improving device yield. In the specific application of channel release processes for substrates that include both shorter channel devices and longer channel devices, the increased overetch margin of the embodiment etching processes may have the advantage of preventing damage to the shorter channel devices (which have already completed the channel release) while the channel release etch is continued on the longer channel devices.

A further advantage of the embodiment etching processes may be to achieve the benefits of the blocking layer and then fully remove the blocking layer without impacting the material composition of the remaining structures. That is, the blocking layer may be removed to expose pristine material surfaces (no persisting modification of the underlying materials). For example, when the blocking layer is formed on structures of a certain material, the atomic concentrations of the certain material before formation and after removal of the blocking layer may advantageously remain the same to within 1% (or even lower).

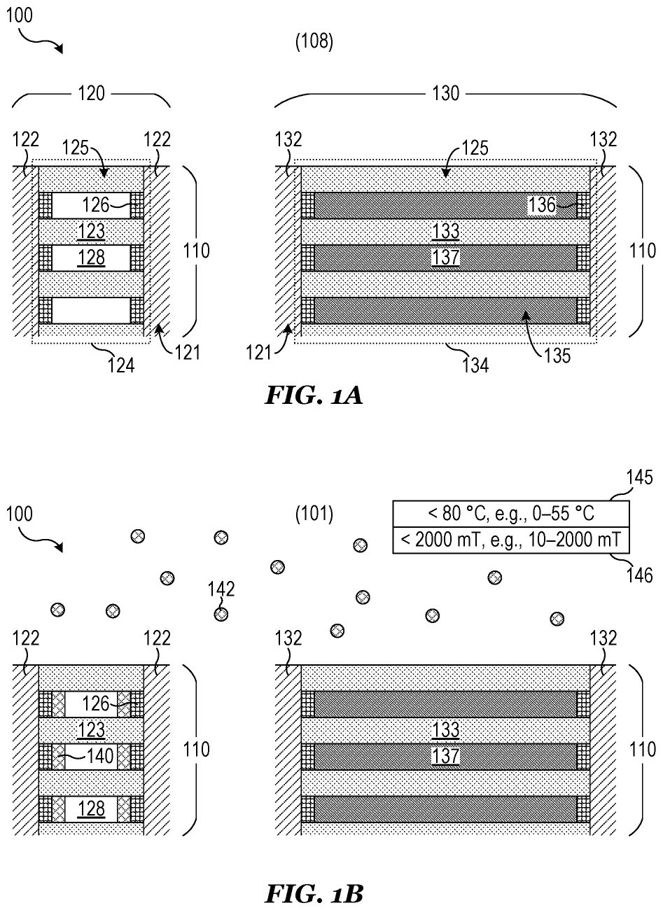

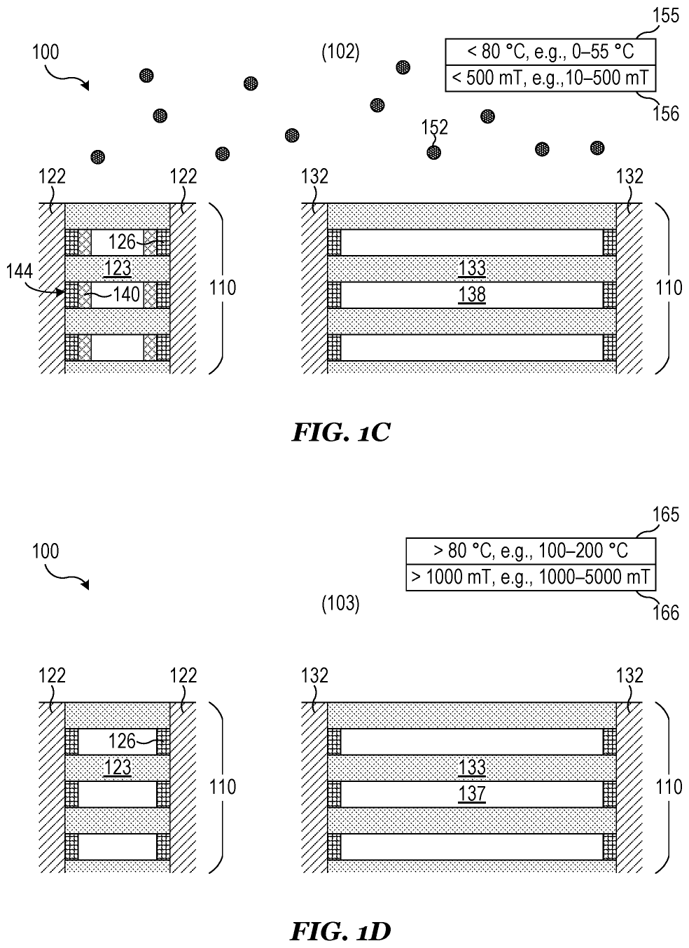

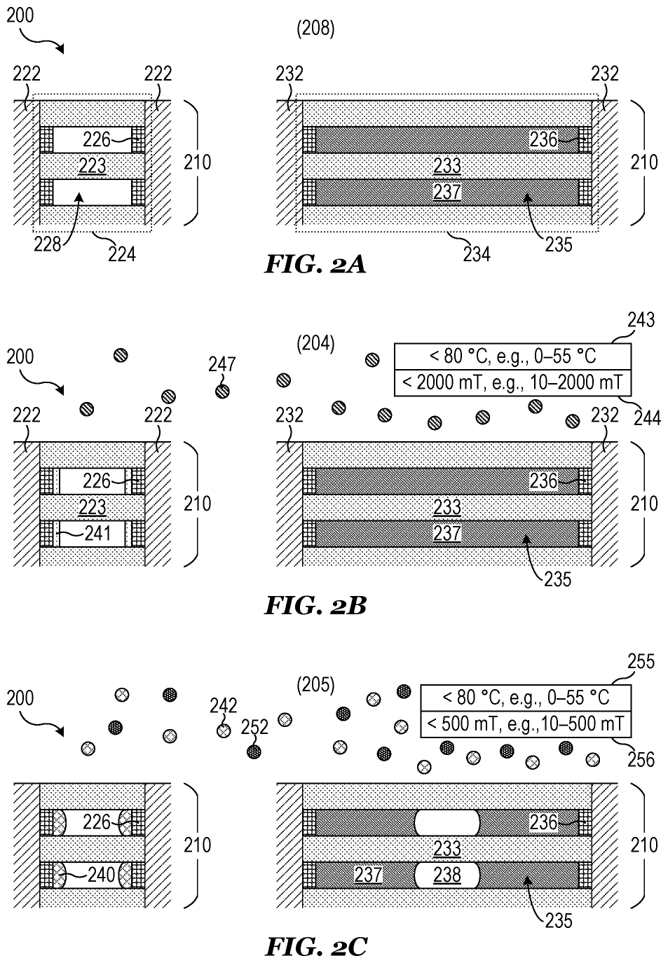

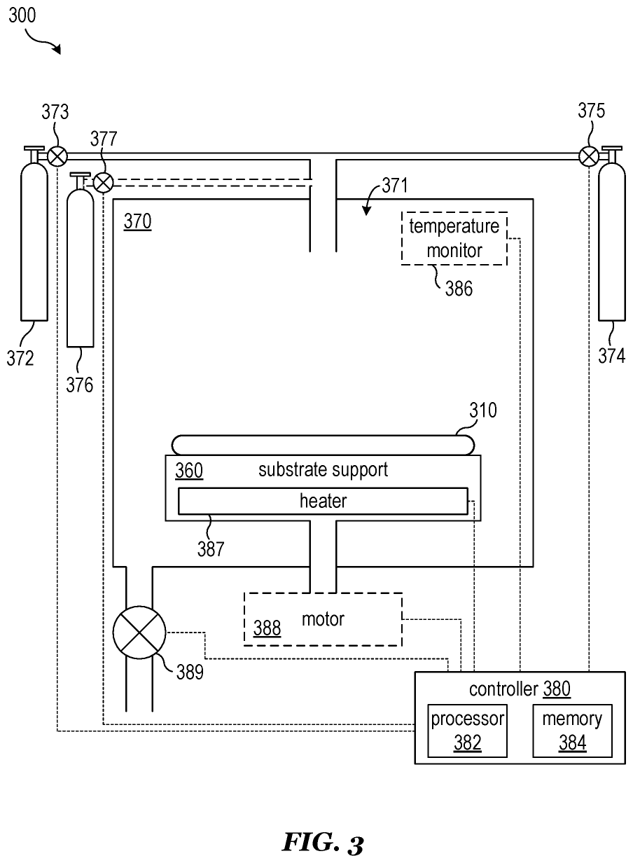

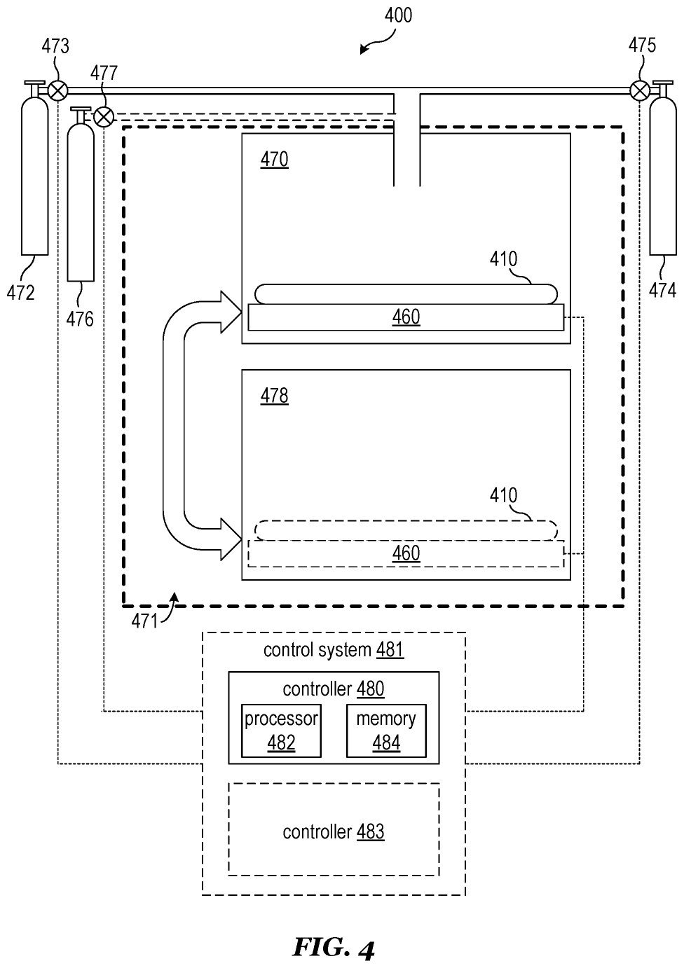

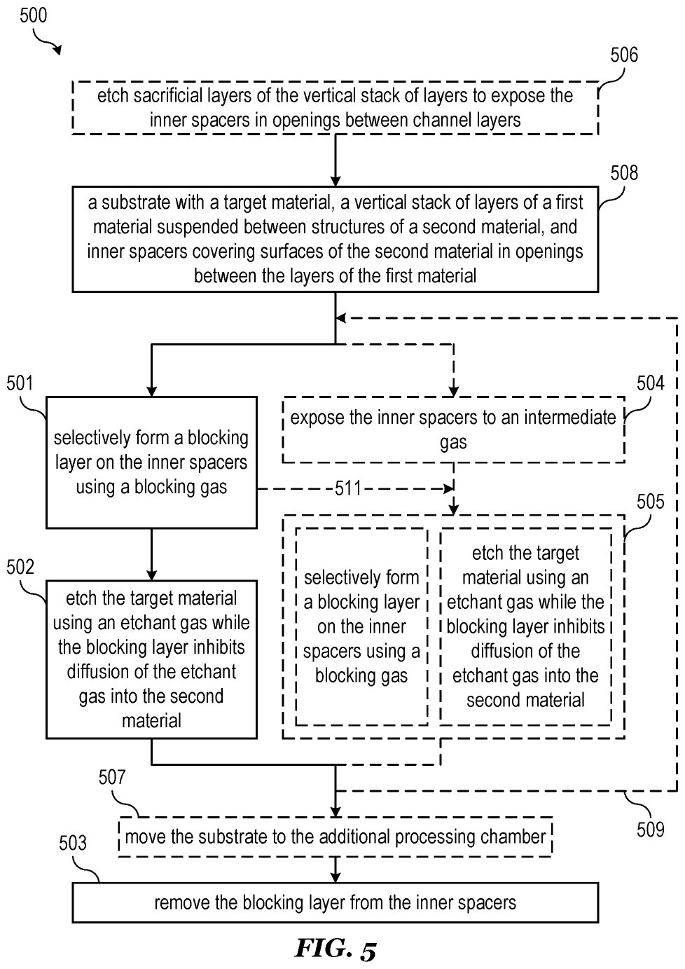

Embodiments provided below describe various etching processes, and in particular, systems and methods for etching processes that include in situ formation of a removable blocking layer. The following description describes the embodiments. FIGS. 1A-1D are used to describe an example etching process. Another example etching process is described using FIGS. 2A-2C. Two example systems that may be used to perform etching processes that include in situ formation of a removable blocking layer are described using FIGS. 3 and 4. An example method of etching a target material is described using FIG. 5.

FIGS. 1A-1D illustrate an example etching process that uses a blocking layer to inhibit diffusion while etching a target material, where FIG. 1A shows an initial state of a substrate with inner spacers in openings of a vertical stack of layers, FIG. 1B shows a selective formation step of forming a blocking layer on the inner spacers, FIG. 1C shows an etch step of etching the target material while the blocking layer inhibits diffusion, and FIG. 1D shows a removal step of removing the blocking layer in accordance with embodiments of the invention. While the etching process described using FIGS. 1A-1D gives specific structures and materials in order to provide context, as mentioned throughout the disclosure, the etching process may also apply to other structures and materials.

Referring to FIG. 1A, an initial state 108 of a substrate 110 of the etching process 100 includes shorter channel devices 120 and longer channel devices 130. The shorter channel devices 120 have a first vertical stack of layers 124 (e.g., a suspended channel structure) with short channel layers 123 suspended between structures 122 of a second material 121 (e.g., source/drain structures). The short channel layers 123 are formed of a first material 125 and are separated by inner spacers 126 disposed in openings 128 between the short channel layers 123.

Similarly, the longer channel devices 130 may have a second vertical stack of layers 134 (e.g., a channel structure with a longer channel length than the shorter channel devices) disposed between structures 132 of the second material 121 (or of a different material in other embodiments). The second vertical stack of layers 134 includes long channel layers 133 of the first material 125 (or of a different material) separated by inner spacers 136 and sacrificial layers 137 that are formed of a target material 135.

The substrate 110 may be any suitable substrate, such as an insulating, conducting, or semiconducting substrate with one or more layers disposed thereon. One example category of possible substrates would be one of the many types of semiconductor wafer (silicon, silicon-on-insulator, germanium, gallium arsenide, etc.). The substrate 110 may include any manner of microelectronic devices, such as semiconductor devices. Additionally, the substrate 110 may be in an intermediate stage of fabrication to form such devices. For example, various electronic components may be included on the substrate 110 such as active components like transistors, gated diodes, and silicon-controlled rectifiers (SCRs), and passive components like resistors, capacitors, inductors, and diodes. The components may be configured to perform tasks like amplification, regulation, and signal modulation by selecting various materials, structures, and arrangements of the components. The components may be arranged in specialized circuits, some of which include memory circuits, such as random access memory (RAM), read-only memory (ROM), and flash memory, digital logic circuits including logic gates, multiplexers, decoders and encoders, flip-flops, and registers, and analog circuits such as signal processors, filters, sensors, and the like. In various embodiments, the substrate 110 is or will be an integrated circuit (IC), ranging from largescale ICs, such as a microcontroller or microprocessor, so smaller, specialized ICs.

The shorter channel devices 120 may be any type of device or intermediate structure (for simplicity reasons, the shorter channel devices 120 are called “devices” even though the structures being referenced can be and often are intermediate structures that will be part of or used to form part of the completed device). In the specific example of the etching process 100, the shorter channel devices 120 include the first vertical stack of layers 124, which may be part of a three-dimensional device (e.g., a multilayer device), such as a GAA transistor like a GAA FET. The doping type of the device may also vary, including p-type (e.g., pFET), n-type (e.g., nFET), mixed type, etc.

The longer channel devices 130 may also be any type of device or intermediate structure that includes the target material 135 of the etching process 100. In this specific example, the longer channel devices 130 include the second vertical stack of layers 134 (a similar structure as the shorter channel devices 120), but the long channel layers 133 have a longer length than the short channel layers 123 of the shorter channel devices 120. The size of the length difference may vary, but is on the order of tens of nanometers in one embodiment. The absolute length of the long channel layers 133 may also vary. For example, the channel length of the longer channel devices 130 may be at least about 50 nm, but may also be longer, such as at least about 100 nm, at least about 200 nm, or even longer.

The short channel layers 123 and the long channel layers 133 may be made from the same material (as shown) or may be different materials. In various embodiments, the first material 125 of the short channel layers 123 and the long channel layers 133 contains Si, and the first material 125 is Si in one embodiment (doped silicon channel layers, for example). The structures 122 and the structures 132 may be source/drain structures for their respective channel structures. In various embodiments, the second material 121 of the structures 122 and the structures 132 contains Si, and the second material 121 is SiGe in one embodiment. While the material of the structures 122 and the structures 132 may be different, they are the same material in one embodiment.

The inner spacers 126 may be formed from a dielectric material, such as an oxide material, for example. In various embodiments, the inner spacers 126 contain oxygen. The inner spacers 126 may also contain Si. In one embodiment, the inner spacers 126 include silicon oxycarbonitride (SiOCN). In some embodiments, the inner spacers 126 include silicon nitride (SiN), and some amount of native oxide has formed on the SiN in one embodiment (e.g., due to exposure to the ambient environment). Of course, other materials may also be selected for use as the inner spacers 126.

The inner spacers 136 may be the same (structurally and/or materially) as the inner spacers 126, as illustrated, or may have differences. In the initial state 108, the inner spacers 126 are in the openings 128 while the inner spacers 136 are located between the structures 132 and the sacrificial layers 137. The target material 135 of the sacrificial layers 137 is a different material than the first material 125. In various embodiments, the target material 135 is a silicon-containing material, and the target material 135 is SiGe in one embodiment.

The initial state 108 is provided as an example starting point for the etching process 100, but other process steps (e.g., that lead to the substrate 110 being in the initial state 108) may be thought of as part of the etching process 100 in some cases. One example might be a preliminary etch step that is used to form the openings 128. For example, prior to the initial state 108, the shorter channel devices 120 of the substrate 110 may include sacrificial layers between the short channel layers 123 (which may be the same or different than the sacrificial layers 137) that are etched in a channel release process for the shorter channel devices 120 that result in the initial state 108.

Referring to FIG. 1B, the substrate 110 is exposed to a blocking gas 142 during a selective formation step 101 of the etching process 100. The blocking gas 142 selectively forms blocking layer 140 on the exposed surfaces of the inner spacers 126 in the openings 128. The blocking gas 142 is selected to (i.e., configured to) interact with the material of the inner spacers 126 so that the blocking layer 140 are formed on the inner spacers 126 while the blocking gas 142 forms little or no material on undesirable surfaces (such as at least not forming a blocking layer on the target material 135, for example).

The blocking gas 142 may be a single gas or a combination of gases. In various embodiments, the blocking gas 142 includes an ammonium precursor, and includes ammonia (NH₃) gas in one embodiment. The blocking gas 142 may also include a fluorine source, such as hydrogen fluoride (HF) gas, in one embodiment. For example, in some embodiments, an ammonium precursor and a fluorine source combine to form ammonium fluoride (AF) as the blocking layer 140. In one embodiment, the inner spacers 126 include silicon, and the blocking layer 140 includes or is entirely ammonium fluorosilicate (AFS). The blocking gas 142 may also include additional gases (e.g., other than those directly involved in the formation of the material of the blocking gas 142). For example, the blocking gas 142 may also include carrier gases (e.g., inert or semi-inert gases such as nitrogen (N₂), noble gases (e.g., argon (Ar), krypton (Kr), etc.), reactive gases, such as catalysts, and others.

The selective formation of the blocking gas 142 may be based on a variety of mechanisms, one of which may be sticking coefficient that varies based on material. For instance, the blocking gas 142 may form a material selected to (i.e., configured to) form quickly on the inner spacers 126 and more slowly on other materials present on the substrate 110 (e.g., sufficiently slowly so as to modulate the deposition regime based on time). In some embodiments, such as for AF and AFS blocking layer materials, the blocking layer 140 may form faster on oxygen-containing materials, such as oxides (including native oxide formed on non-oxides, such as SiN, for example). In some cases, substantially no material may form on other materials, such as the target material 135 of the sacrificial layers 137, during the formation of the blocking layer 140. This may allow time-based selective deposition by exposing the substrate 110 to the blocking gas 142 for a duration long enough to form the blocking layer 140, but short enough to prevent significant blocking material from building up elsewhere.

The selective formation step 101 may include other controllable parameters, such as temperature (substrate, chamber, gas, etc.) and pressure (which may be modulated by controlling flowrates of the constituent gases of the blocking gas 142, vacuum pumping speed, etc.). For example, the formation temperature 145 (e.g., the substrate temperature) of the selective formation step 101 may be less than about 80° C., and is in the range of about 0° C. to about 55° C. in some embodiments. Similarly, the formation pressure 146 of the selective formation step 101 may be less than about 2000 mT, and is in the range of about 10 mT to about 2000 mT in one embodiment.

Referring to now FIG. 1C, the substrate 110 is exposed to an etchant gas 152 in a etch step 102 of the etching process 100. The etchant gas 152 is configured to etch the target material 135 of the sacrificial layers 137 to form openings 138 without etching the long channel layers 133. During the etch step 102, the blocking layer 140 is configured to protect the structures 122 from the etchant gas 152 (i.e., inhibit or block diffusion of the etchant gas 152 through the inner spacers 126 and into the structures 122, such as into SiGe source/drain structures, for example). In particular, the inner spacers 126 cover second material surfaces 144 of the structures 122, but may not prevent diffusion of the etchant gas 152 for the additional etching time needed to release the long channel layers 133 forming the openings 138.

The etchant gas 152 may also be a single gas or a combination of gases. Some of the gases of the etchant gas 152 may be the same as the blocking gas 142, but some gases are different. The etchant gas 152 includes at least one fluorine-containing gas in various embodiments, and includes chlorine trifluoride (ClF₃) in some embodiments, and fluorine (F₂) gas in some embodiments. For example, the etchant gas 152 may include both ClF₃ gas and F₂. In one embodiment, the etchant gas 152 includes ClF₃ gas, F₂ gas, and HF gas (while still possibly including other gases, such as Ar, N₂, etc.).

The degree of overetch that the shorter channel devices 120 can tolerate while the etching process 100 still has the desired results (e.g., yield) may be referred to as the overetch margin of the etching process 100. For example, overetch margin for the etching process 100 may be the amount of etching that the smallest etching target on the substrate 110 can withstand (e.g., the shorter channel devices 120) and may need to be at least large enough to accommodate the largest etching target on the substrate 110 (e.g., the longer channel devices 130). In the specific application of a channel release process shown here, it may be desirable to increase the overetch margin to allow for the completion of the channel release of the long channel layers 133 without damaging the shorter channel devices 120.

In conventional etching processes, damage from overetching may begin for the shorter channel devices 120 very early (e.g., immediately after the short channel layers 123 are fully released) and quickly become untenable, such as about 10% of the sites being damaged at about 50 nm overetch and rapidly climbing to greater than 75% damaged sites at about 125 nm overetch. In contrast, damaged sites may advantageously not even appear until about 200 nm overetch (or higher), such as when an AF or AFS blocking layer is used.

Similar to the selective formation step 101, the etch step 102 may be performed at certain temperatures and pressures. For example, the etch temperature 155 of the etch step 102 may be less than about 80° C., and is in the range of about 0° C. to about 55° C. in some embodiments. This may be similar to the ranges of the formation temperature 145, although the specific temperature values or ranges do not have to be identical between the selective formation step 101 and the etch step 102 for a given implementation of the etching process 100. Similarly, the etch pressure 156 of the etch step 102 may be less than about 500 mT, and is in the range of about 10 mT to about 500 mT in one embodiment. In various embodiments, the etch pressure 156 is lower than the formation pressure 146 (e.g., a relatively low pressure compared to the relatively medium pressure of the selective formation step 101).

Now turning to FIG. 1D, the blocking layer 140 is removed during a removal step 103 of the etching process 100. For example, the material of the blocking layer 140 may be volatile at elevated temperatures, allowing for the blocking layer 140 to be removed by applying heat to the substrate 110 during the removal step 103. In various embodiments, a removal temperature 165 of the removal step 103 is higher than both the formation temperature 145 and the etch temperature 155, such as greater than about 80° C. in some embodiments. In one embodiment, the removal temperature 165 is in the range of about 100° C. to about 200° C.

The removal step 103 may also be performed at a relatively high temperature compared to the previous steps. For example, a removal pressure 166 of the removal step 103 is higher than one or both of the formation pressure 146 and the etch pressure 156 in various embodiments. In some embodiments, the removal pressure 166 is greater than about 1000 mT, and the removal pressure 166 is in the range of about 1000 mT to about 5000 mT in one embodiment.

Based on the selection of the material of the blocking layer 140, the removal step 103 may have the advantage of being easily removable, such as by simply elevating the temperature (e.g., baking) of the substrate 110 to a temperature within the thermal budget. Moreover, the resulting surfaces (including the inner spacers 126) may be pristine after the removal step 103. That is, the atomic concentrations of the inner spacers 126 before formation and after removal of the blocking layer 140 may advantageously remain the same to within 1% (or even lower).

FIGS. 2A-2C illustrate another example etching process that uses a blocking layer to inhibit diffusion while etching a target material, where FIG. 2A shows an initial state of a substrate with inner spacers in openings of a vertical stack of layers, FIG. 2B shows an optional pretreatment step that modifies surfaces of the inner spacers, and FIG. 2C shows a combined step of selectively forming the blocking layer on the inner spacers while etching the target material in accordance with embodiments of the invention. The etching process of FIGS. 2A-2C may be a specific implementation of other etching processes described herein such as the etching process of FIGS. 1A-1D, for example. Similarly labeled elements may be as previously described.

Referring to FIG. 2A, an etching process 200 begins with an initial state 208 of a substrate 210 that is similar to the initial state 108 of the etching process 100 where the substrate 210 includes shorter channel devices and longer channel devices. The shorter channel devices have a first vertical stack of layers 224 (e.g., a suspended channel structure) with short channel layers 223 suspended between structures 222 (e.g., source/drain structures). The short channel layers 223 are separated by inner spacers 226 disposed in openings 228 between the short channel layers 223. The longer channel devices may have a second vertical stack of layers 234 disposed between structures 232. The second vertical stack of layers 234 includes long channel layers 233 separated by inner spacers 236 and sacrificial layers 237 that are formed of a target material 235.

It should be noted that here and in the following a convention has been adopted for brevity and clarity wherein elements adhering to the pattern [x10] where ‘x’ is the figure number may be related implementations of a substrate in various embodiments. For example, the substrate 210 may be similar to the substrate 110 except as otherwise stated. An analogous convention has also been adopted for other elements as made clear by the use of similar terms in conjunction with the aforementioned numbering system.

Referring to FIGS. 2B and 2C, the etching process 200 differs from the etching process 100 in that the selective formation and etching steps are combined into a combined step 205 during which the substrate 210 is exposed to both a blocking gas 242 and an etchant gas 252. Specifically, a blocking layer 240 is formed on the inner spacers 226 concurrently with the etching of the target material 235 to form openings 238. Additionally, an optional pretreatment step 204 may also be included to pretreat surfaces of the inner spacers 226 in preparation for the formation of the blocking layer 240 using the blocking gas 242. During the optional pretreatment step 204, the substrate 210 may be exposed to an intermediate gas 247 that modifies the inner spacers 226 to form modified inner spacer surfaces 241. After the combined step 205, the sacrificial layers 237 may be gone (e.g., a full channel release of the long channel layers 233 extending the openings 238 to the inner spacers 236) while material of the blocking layer 240 remains on the inner spacers 226. The etching process 200 may then proceed to a removal step, which is the same as the removal step 103 of the etching process 100 of FIG. 1D.

The blocking gas 242 and the etchant gas 252 may be the same or different as the analogous gases in the selective formation step 101 and the etch step 102 of the etching process 100. For example, the gases included in the etchant gas 252 may depend on the target material 235 which may be the same or different than the target material 135. However, in some cases, the inclusion of the blocking gas 242 may make changes to the etchant gas 252 desirable and the etchant gas 252 may be different despite the target material 235 being the same as the target material 135. Similarly, the blocking gas 242 may be the same as the blocking gas 142 (such as when the optional pretreatment step 204 is not included), but may also be different. In one embodiment, the intermediate gas 247 includes NH₃ gas while the blocking gas 242 includes HF gas.

The optional pretreatment step 204 and the combined step 205 may be performed at certain temperatures and pressures. These may have some similarity to the temperatures and pressures of corresponding steps in the etching process 100. For example, an etch temperature 255 and an etch pressure 256 of the combined step 205 may be similar to that of the etch step 102 of etching process 100 (e.g., despite the inclusion of the blocking gas 242, for example). Although not directly analogous, an intermediate temperature 243 and an intermediate pressure 244 of the optional pretreatment step 204 (when included) may be similar to the formation temperature 145 and the formation pressure 146 of the selective formation step 101 of the etching process 100. For example, this may be thought of as similar in the sense that the bare surfaces of the inner spacers 226 may be affected by one or more similar gases as the inner spacers 126 in the selective formation step 101, such as NH₃ gas, for example.

FIG. 3 illustrates an example system that may be used to perform one or more steps of the etching processes without breaking vacuum in accordance with embodiments of the invention. The system of FIG. 3 may be used to perform some or all of any of the etching processes and methods apparent from the descriptions herein, such as the etching processes of FIGS. 1A-1D and 2A-2C and the method of FIG. 5, as examples. Similarly labeled elements may be as previously described.

Referring to FIG. 3, a system 300 (e.g., an etching system) includes a substrate support 360 disposed within a vacuum environment 371, such as a processing chamber 370, and configured to support a substrate 310. A blocking source 372 (e.g., a gas source or sources that include a blocking gas), an etchant source 374 (e.g., a gas source or sources including one or more reactive gases configured to etch a target material) are fluidically coupled to the processing chamber 370 through one or more valves, such as a blocking valve 373 and an etchant valve 375. Additional gas sources and valves may also be included in the system 300. For example, an optional additional gas source 376 (e.g., a gas source or sources including additional gases, which may be any type of gas, such as carrier gases, additional reactants and precursors, stabilizers, catalysts and others) may be fluidically coupled to the processing chamber 370 through an optional additional gas valve 377. An exhaust valve 389 is also included to evacuate the processing chamber 370 during the processes performed therein, such as the etching processes as described in the foregoing, preceding or subsequent etching processes, and others.

The processing chamber 370 may be any suitable etch chamber and may also be usable as a deposition chamber. In various embodiments, process steps of an etching process performed by the system 300 (e.g., a selective formation step, an etching step, a removal step, etc.) may be performed without generating plasma. In other cases, plasma may be generated during some or all of the process steps. The processing chamber 370 may be used for some or all of the process steps of an etching process. In various embodiments, a selective formation step of a blocking layer and an etching step of a target material are performed in situ in the processing chamber 370 (i.e., in place in the same chamber). In one embodiment, the selective formation step, the etching step, and a removal step of the blocking layer are all performed in situ in the processing chamber 370. In another embodiment, the removal step is performed in a different chamber than the selective formation step and the etching step.

An optional temperature monitor 386 may also be included to monitor and/or aid in controlling the temperature of the substrate 310 and the environment in the processing chamber 370. A temperature control device 387 (heater, cooler, or combination thereof) may be included to elevate or reduce the temperature of the substrate 310 above/below the equilibrium temperature at the substrate 310 during the process steps (although some process steps may be performed at ambient temperatures). An optional motor 388 may also be included to improve etch/deposition uniformity.

A controller 380 is operatively coupled to the one or more valves (the blocking valve 373, the etchant valve 375, the optional additional gas valve 377, etc.), and may be operatively coupled to any of the optional temperature monitor 386, the temperature control device 387, the optional motor 388, and the exhaust valve 389. The controller 380 includes a processor 382 and a memory 384 (i.e., a non-transitory computer-readable medium) that stores a program including instructions that, when executed by the processor 382, perform processes such as the etching processes described herein. For example, the memory 384 may have volatile memory (e.g., random access memory (RAM)) and non-volatile memory (e.g., flash memory). Alternatively, the program may be stored in physical memory at a remote location, such as in cloud storage. The processor 382 may be any suitable processor, such as the processor of a microcontroller, a general-purpose processor (such as a central processing unit (CPU), a microprocessor, a field-programmable gate array (FPGA), an application-specific integrated circuit (ASIC), and others.

FIG. 4 illustrates another example system that may be used to perform one or more steps of the etching processes without breaking vacuum in accordance with embodiments of the invention. The system of FIG. 4 may be used to perform some or all of any of the etching processes and methods apparent from the descriptions herein, such as the etching processes of FIGS. 1A-1D and 2A-2C and the method of FIG. 5, as examples. Similarly labeled elements may be as previously described.

Referring to FIG. 4, a system 400 is similar to the system 300 except that the system 400 includes two processing chambers (a processing chamber 470 and at least one additional processing chamber 478) in a vacuum environment 471. That is, the system 400 may be a platform that includes several tools and is configured to perform processes in two or more regions (e.g., chambers) without breaking vacuum (e.g., in the vacuum environment 471). Of course, the pressure in the various regions of the system 400 may be individually controlled relative to one another, but the system 400 is a closed system that maintains the vacuum environment 471 below external pressures and prevents gases from the external environment from entering the vacuum environment 471. The processing chamber 470 may be similar to the processing chamber 370 (i.e., various additional features and components may be included for the processing chamber 470 as the processing chamber 370, but many of these features are not illustrated in FIG. 4 for the sake of simplicity).

The system 400 includes a substrate support 460 disposed within the vacuum environment 471 and configured to support a substrate 410. For example, the substrate support 460 may be configured to be moved between the processing chamber 470 and the vacuum environment 471. Alternatively, the substrate 410 may be transferred between substrate supports when being moved between the processing chamber 470 and the vacuum environment 471. A blocking source 472, an etchant source 474, and an optional additional gas source 476 are fluidically coupled to the processing chamber 470 through one or more valves, such as a blocking valve 473 an etchant valve 475, and an optional additional gas valve 477.

The processing chamber 470 may be any suitable etch chamber and may also be usable as a deposition chamber. The processing chamber 470 may be used for some of the process steps of an etching process while the additional processing chamber 478 may be used for other process steps of the etching process. The additional processing chamber 478 may be any suitable chamber (e.g., for removal of a blocking layer, for example), such as a baking chamber. In various embodiments, all of the process steps of an etching process are performed in the system 400 without breaking vacuum (i.e., in the vacuum environment 471). In one embodiment, a selective formation step of a blocking layer and an etching step of a target material are performed in situ in the processing chamber 470 (i.e., in place in the same chamber) while a removal step of the blocking layer is performed in the additional processing chamber 478.

A controller 480 (e.g., optionally as part of a control system 481, which may include one or more additional controllers, such as controller 483, that are specialized to control various aspects of the system 400) is operatively coupled to the one or more valves (the blocking valve 473, the etchant valve 475, the optional additional gas valve 477, etc.), and may be operatively coupled to the substrate support 460 (or various substrate transport mechanisms), as well as any optional components (not shown) like an optional temperature monitor, optional temperature control device, optional motor, exhaust valve. The controller 480 includes a processor 482 and a memory 484 (i.e., a non-transitory computer-readable medium) that stores a program including instructions that, when executed by the processor 482, perform processes such as the etching processes described herein.

FIG. 5 illustrates an example method etching a target material of a substrate that also includes a vertical stack of layers of a first material suspended between structures of a second material in accordance with embodiments of the invention. The method of FIG. 5 may be combined with other methods and performed using the systems and apparatuses as described herein. For example, the method of FIG. 5 may be combined with any of the embodiments of FIGS. 1A-4. Although shown in a logical order, the arrangement and numbering of the steps of FIG. 5 are not intended to be limited. The method steps of FIG. 5 may be performed in any suitable order or concurrently with one another as may be apparent to a person of skill in the art.

Referring to FIG. 5, a method 500 of etching a target material may start at an initial state 508 with a substrate including the target material that also includes a vertical stack of layers of a first material (e.g., channel layers, such as Si channel layers) suspended between structures of a second material (e.g., source/drain structures, such as SiGe source/drain structures). Although there is no strict structural requirement for the method 500, the vertical stack of layers is an example category of applications to which the method 500 may be well-suited. The vertical stack of layers may be an intermediate or final structure that is part of a three-dimensional device, such as a three-dimensional channel structure including suspended channel layers of a GAA transistor (e.g., GAA FET).

Inner spacers (e.g., comprising oxygen, such as an oxide), may be located in openings between the layers of the first material arranged so that they cover surfaces of the second material, such as directly contacting the surfaces of the second material structures in the openings, but direct contact is not required. In some cases, additional structures may be included between the inner spacers and the second material or the inner spacers may be set apart from the second material within the openings.

The length of the layers in the vertical stack (e.g., the channel length between source/drain structures) may be chosen to be any desired value, but is shorter than the length of the structures that include the target material in some embodiments. For example, in the specific example where the vertical stack of layers is a channel structure included in shorter channel devices, the target material may be sacrificial layers between channel layers of a longer channel device. In various embodiments, the channel length of the longer channel devices is greater than about 50 nm, and may be greater than at least about 100 nm in some embodiments. Of course, as discussed in the foregoing, embodiment etching processes (i.e., performed by the method 500) undesirable structural damage may be entirely avoided for at least about 200 nm of overetch (or even more). and therefore, in some cases, the longer channel devices may also have channel lengths of at least about 200 nm while still achieving the desired results.

In a selective formation step 501, a blocking layer is selectively formed on the inner spacers using a blocking gas (e.g., using a controller operatively coupled to one or more valves and executing a program that causes the one or more valves to fluidically couple the blocking gas with a processing chamber that contains the substrate). The inner spacers may include an oxygen-containing material such as an oxide or a dielectric material with a native oxide formed thereon. In one embodiment, the inner spacers include SiOCN (silicon oxycarbonitride). In other embodiments, the inner spacers include SiN (silicon nitride), such as with native oxide formed on the surface.

The blocking gas includes one or more gases that selective deposit on the material of the inner spacers. For example, the blocking gas may form a blocking layer on oxygen-containing materials, oxides, nitrides, etc. at a sufficiently shorter timescales than the blocking layer forms on the target material so that providing the blocking gas for a short enough duration results in the blocking layer selectively forming on the inner spacers. In various embodiments, the blocking gas includes ammonia (such as ammonia gas or a gaseous compound that includes an ammonia precursor). In some embodiments, the blocking gas includes at least one fluorine-containing gas and includes HF (hydrogen fluoride) in one embodiment.

While the blocking layer may be any material that will selectively deposit on the material of the inner spacer and can be removed without affecting the inner spacer material, the blocking layer may be a compound including ammonium and fluorine. In one embodiment, the blocking layer is AF (ammonium fluoride). In another embodiment, the blocking layer is AFS (ammonium fluorosilicate).

In some embodiments, rather than beginning with a substrate in the initial state 508, the method 500 may include an optional preliminary etch step 506 during which sacrificial layers of the vertical stack of layers (e.g., of shorter channel devices) are etched to expose the inner spacers in the openings between the layers of the first material (e.g., between the channel layers as part of a channel release process of the shorter channel devices). The optional preliminary etch step 506 may or may not be performed concurrently with the first part of a channel release process of longer channel devices. For example, in one embodiment, the optional preliminary etch step 506 is also a preliminary etch step of sacrificial layers of between channel layers of longer channel devices (that does not reach an endpoint because the channel length is longer). Since the sacrificial layers of the longer channel devices are not fully removed, inner spacers that may be included in the longer channel devices are not exposed and therefore no blocking layer would form on the longer channel devices.

In an etch step 502, the target material is etched using an etchant gas while the blocking layer inhibits diffusion of the etchant gas into the second material (e.g., using the controller, or another controller, to cause the one or more valves to fluidically couple the etchant gas with the processing chamber). For instance, the target material may be sacrificial layers, such as SiGe layers, of a vertical stack of layers of a longer channel device that is etched using a fluorine-containing gas, such as ClF₃, F₂, or a combination thereof. The blocking layer inhibits diffusion of the etchant gas through the inner spacers and into the second material. That is, diffusion is at least slowed down and may be prohibited entirely (at least on timescales of similar order of magnitude as the etch step 502).

The etch step 502 may be performed after the selective formation step 501, as shown. Alternatively, etching the target material may be performed concurrently (i.e., simultaneously) with selectively forming the blocking layer, as shown in combined step 505. In some implementations, the blocking gas or a component of the blocking gas may be included in the etch step 502 so that the blocking layer continues to be formed while etching the target material even when the selective formation step 501 is included as a separate selective formation step (shown as the arrow 511). Further, the selective formation step 501 and the etch step 502 may be repeated as a cycle 509 (e.g., in order to maintain protection of the second material structures during further etching of the target material if the blocking layer is consumed or otherwise modified during the etch step 502).

The blocking gas for the combined step 505 may be the same or different than the blocking gas for the selective formation step 501. As an example of when the blocking gas may be different, an optional pretreatment step 504 may be included during which the inner spacers (e.g., an oxygen-containing material such as an oxide, or another dielectric material such as a nitride) are exposed to an intermediate gas and then further precursors of the blocking layer are included in the blocking gas of the combined step 505. In analogy with the previous specific examples of a blocking gas, the intermediate gas may include ammonia gas while the blocking gas provided during the combined step 505 may include HF gas (with or without ammonia gas).

After the etch step 502 (or the combined step 505, or a cycle 509) has reached the desired endpoint for etching the target material, the blocking layer is removed from the inner spacers in a removal step 503. During the removal step 503, the blocking layer is removed without affecting the material composition of the inner spacers. For example, when the inner spacers include an oxygen-containing material at exposed surfaces of the inner spacers, the blocking layer is removed from the oxygen-containing material and the oxygen-containing material has the same composition (i.e., atomic concentrations) before the selective formation step 501 as after the removal step 503 (e.g., to some tolerance such as within one percent of the atomic concentrations before the selective formation step 501, or even lower).

In various embodiments, the material of the blocking layer is selected so that it may be fully removable (i.e., configured to be fully removable). The bonding of the blocking layer to the inner spacers may be fully reversible, such as by providing a certain threshold of energy (i.e., activation energy, which may be provided in the form of thermal energy, for example) to break the bonds and remove the blocking layer. The material of the blocking layer may be volatilized at temperatures in the above a certain range, resulting in decomposition of the material. For example, the removal step 503 may include exposing the vertical stack to a temperature of at least 80° C. (such as using a temperature control device in the substrate holder). In the specific example of AF, the AF blocking layer may then sublime as its precursor gases, which would be ammonia gas and HF gas in this case.

In various embodiments, temperature may also be controlled (substrate temperature, processing gas temperature, etc.) during one or both of the selective formation step 501 and the etch step 502 (and the optional pretreatment step 504 and the combined step 505 when included). For example, if elevated temperature results in the removal of the blocking layer, then it may be desirable to ensure that the substrate temperature is maintained below the threshold (e.g., 80° C.) before the removal step 503, such as using one or more substrate temperature control devices operatively coupled to the controller, or an additional controller. In some embodiments, the gap between the temperature during the removal step 503 and the temperature during other steps may be larger. In one specific example, the substrate is maintained at temperatures below about 55° C. during both the selective formation step 501 and the etch step 502 while the substrate is maintained at temperatures above about 100° C. during the removal step 503.

The selective formation step 501 and the etch step 502 (and the optional pretreatment step 504 and the combined step 505 when included) may be performed in the same processing chamber (e.g., an etching chamber). The removal step 503 may also be performed in the same processing chamber. However, in some embodiments it may be desirable to perform the removal step 503 in a different (i.e., additional) processing chamber, such as to maintain cleanliness in the etching chamber. In this case, the method 500 may also include a loading step 507 where the substrate is moved to (i.e., loaded into) the additional processing chamber between the etch step 502 (or the combined step 505) and the removal step 503. Notably, this may still be performed in the same vacuum environment of a system that is being used to perform the method 500 (such as the system 400 of FIG. 4, for example). That is, the method 500 may be performed without breaking vacuum all in the same processing chamber or in multiple processing chambers of the same platform.

Example embodiments of the invention are summarized here. Other embodiments can also be understood from the entirety of the specification as well as the claims filed herein.

Example 1. A method of etching a target material of a substrate that also includes a vertical stack of layers of a first material suspended between structures of a second material, the method including: selectively forming a blocking layer on an oxygen-containing material using ammonia gas and at least one fluorine-containing gas, the oxygen-containing material covering surfaces of the second material in openings between the layers of the first material; etching the target material using an etchant gas, the blocking layer inhibiting diffusion of the etchant gas into the second material; and removing the blocking layer from the oxygen-containing material by exposing the vertical stack to a temperature of at least 80° C.

Example 2. The method of example 1, where selectively forming the blocking layer and etching the target material are both performed in the same processing chamber.

Example 3. The method of one of examples 1 and 2, where etching the target material is performed after selectively forming the blocking layer.

Example 4. The method of one of examples 1 and 2, where selectively forming the blocking layer is performed concurrently with etching the target material.

Example 5. The method of example 4, where selectively forming the blocking layer includes exposing the oxygen-containing material to the ammonia gas before etching the target material, and then exposing the oxygen-containing material to the at least one fluorine gas concurrently with etching the target material.

Example 6. The method of one of examples 1 to 5, where the blocking layer includes ammonium fluorosilicate or ammonium fluoride.

Example 7. The method of one of examples 1 to 6, where the at least one fluorine-containing gas includes hydrogen fluoride (HF).

Example 8. The method of one of examples 1 to 7, where selectively forming the blocking layer and etching the target material are performed at temperatures less than 80° C.

Example 9. The method of one of examples 1 to 8, where selectively forming the blocking layer, etching the target material, and removing the blocking layer are performed without breaking vacuum.

Example 10. The method of one of examples 1 to 9, where atomic concentrations of the oxygen-containing material before selectively forming the blocking layer are within one percent of atomic concentrations of the oxygen-containing material after removing the blocking layer.

Example 11. The method of one of examples 1 to 10, further including repeating selectively forming the blocking layer and etching the target material as a cycle before removing the blocking layer.

Example 12. A channel release method for longer channel devices of a substrate that also includes shorter channel devices, the method including performing the following steps without breaking vacuum: selectively forming a blocking layer on inner spacers of the shorter channel devices, the inner spacers covering surfaces of silicon germanium (SiGe) source/drain structures in openings between silicon (Si) layers suspended between the SiGE source/drain structures; etching SiGe layers of the longer channel devices using an etchant gas, the blocking layer inhibiting diffusion of the etchant gas into the SiGe source/drain structures; and removing the blocking layer from the inner spacers by exposing the shorter channel devices to a temperature of at least 80° C.

Example 13. The channel release method of example 12, where selectively forming the blocking layer on the inner spacers of the shorter channel devices and etching the SiGe layers of the longer channel devices are performed in the same processing chamber.

Example 14. The channel release method of one of examples 12 and 13, further including: etching SiGe layers of the shorter channel devices to expose the inner spacers in the openings using the etchant gas before selectively forming the blocking layer.

Example 15. The channel release method of one of examples 12 to 14, where the blocking layer includes ammonium fluorosilicate or ammonium fluoride, and where the inner spacers include silicon oxycarbonitride (SiOCN).

Example 16. The channel release method of one of examples 12 to 14, where the blocking layer includes ammonium fluorosilicate or ammonium fluoride, and where the inner spacers include silicon nitride (SiN) and native oxide.

Example 17. The channel release method of one of examples 12 to 16, where the longer channel devices include a channel length of at least about 50 nm.

Example 18. A system including: a processing chamber; a substrate support configured to support a substrate within the processing chamber, the substrate including a target material and a vertical stack of layers of a first material suspended between structures of a second material; one or more valves configured to fluidically couple a blocking gas and an etchant gas to the processing chamber; and a controller operatively coupled to the one or more valves, the controller including a processor and a non-transitory computer-readable medium storing a program including instructions that, when executed by the processor, perform a method without breaking a vacuum environment of the system, the method including: selectively forming, in the processing chamber, a blocking layer on an inner spacer material covering surfaces of the second material in openings between the layers of the first material using the blocking gas; etching, in the processing chamber, the target material using the etchant gas, the blocking layer inhibiting diffusion of the etchant gas into the second material; and removing the blocking layer from the inner spacer material.

Example 19. The system of example 18, further including: an additional processing chamber fluidically coupled to the vacuum environment of the system, the method further including moving the substrate to the additional processing chamber, where removing the blocking layer is performed in the additional processing chamber.

Example 20. The system of one of examples 18 and 19, further including: one or more substrate temperature control devices operatively coupled to the controller, where selectively forming the blocking layer and etching the target material include maintaining the substrate at temperatures below about 55° C. using the one or more substrate temperature control devices, and where removing the blocking layer includes maintaining the substrate at temperatures above about 100° C. using the one or more substrate temperature control devices.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of etching a target material of a substrate that also comprises a vertical stack of layers of a first material suspended between structures of a second material, the method comprising:
selectively forming a blocking layer on an oxygen-containing material using ammonia gas and at least one fluorine-containing gas, the oxygen-containing material covering surfaces of the second material in openings between the layers of the first material;
etching the target material using an etchant gas, the blocking layer inhibiting diffusion of the etchant gas into the second material; and
removing the blocking layer from the oxygen-containing material by exposing the vertical stack to an elevated temperature relative to that of selectively forming the blocking layer.

2. The method of claim 1, wherein selectively forming the blocking layer and etching the target material are both performed in the same processing chamber.

3. The method of claim 1, wherein etching the target material is performed after selectively forming the blocking layer.

4. The method of claim 1, wherein selectively forming the blocking layer is performed concurrently with etching the target material.

5. The method of claim 4, wherein selectively forming the blocking layer comprises exposing the oxygen-containing material to the ammonia gas before etching the target material, and then exposing the oxygen-containing material to the at least one fluorine gas concurrently with etching the target material.

6. The method of claim 1, wherein the blocking layer comprises ammonium fluorosilicate or ammonium fluoride.

7. The method of claim 1, wherein the at least one fluorine-containing gas comprises hydrogen fluoride (HF).

8. The method of claim 1, wherein selectively forming the blocking layer and etching the target material are performed at temperatures less than 80° C.

9. The method of claim 1, wherein selectively forming the blocking layer, etching the target material, and removing the blocking layer are performed without breaking vacuum.

10. The method of claim 1, wherein atomic concentrations of the oxygen-containing material before selectively forming the blocking layer are within one percent of atomic concentrations of the oxygen-containing material after removing the blocking layer.

11. The method of claim 1, further comprising repeating selectively forming the blocking layer and etching the target material as a cycle before removing the blocking layer.

12. A channel release method for longer channel devices of a substrate that also comprises shorter channel devices, the method comprising performing the following steps without breaking vacuum:
selectively forming a blocking layer on inner spacers of the shorter channel devices, the inner spacers covering surfaces of silicon germanium (SiGe) source/drain structures in openings between silicon (Si) layers suspended between the SiGe source/drain structures;
etching SiGe layers of the longer channel devices using an etchant gas, the blocking layer inhibiting diffusion of the etchant gas into the SiGe source/drain structures; and
removing the blocking layer from the inner spacers by exposing the shorter channel devices to an elevated temperature relative to that of selectively forming the blocking layer.

13. The channel release method of claim 12, wherein selectively forming the blocking layer on the inner spacers of the shorter channel devices and etching the SiGe layers of the longer channel devices are performed in the same processing chamber.

14. The channel release method of claim 12, further comprising:
etching SiGe layers of the shorter channel devices to expose the inner spacers in the openings using the etchant gas before selectively forming the blocking layer.

15. The channel release method of claim 12,
wherein the blocking layer comprises ammonium fluorosilicate or ammonium fluoride, and
wherein the inner spacers comprise silicon oxycarbonitride (SiOCN).

16. The channel release method of claim 12,
wherein the blocking layer comprises ammonium fluorosilicate or ammonium fluoride, and
wherein the inner spacers comprise silicon nitride (SiN) and native oxide.

17. The channel release method of claim 12, wherein the longer channel devices comprise a channel length of at least about 50 nm.

18. A system comprising:
a processing chamber;
a substrate support configured to support a substrate within the processing chamber, the substrate comprising a target material and a vertical stack of layers of a first material suspended between structures of a second material;
one or more valves configured to fluidically couple a blocking gas and an etchant gas to the processing chamber; and
a controller operatively coupled to the one or more valves, the controller comprising a processor and a non-transitory computer-readable medium storing a program including instructions that, when executed by the processor, perform a method without breaking a vacuum environment of the system, the method comprising:
selectively forming, in the processing chamber, a blocking layer on an inner spacer material covering surfaces of the second material in openings between the layers of the first material using the blocking gas;
etching, in the processing chamber, the target material using the etchant gas, the blocking layer inhibiting diffusion of the etchant gas into the second material; and
removing the blocking layer from the inner spacer material.

19. The system of claim 18, further comprising:
an additional processing chamber fluidically coupled to the vacuum environment of the system, the method further comprising moving the substrate to the additional processing chamber, wherein removing the blocking layer is performed in the additional processing chamber.

20. The system of claim 18, further comprising:
one or more substrate temperature control devices operatively coupled to the controller, wherein selectively forming the blocking layer and etching the target material comprise maintaining the substrate at temperatures below about 55° C. using the one or more substrate temperature control devices, and wherein removing the blocking layer comprises maintaining the substrate at temperatures above about 100° C. using the one or more substrate temperature control devices.
